(19) United States
(12) Patent Application Publication
(10) Pub. No.: US 2011/0241060 A1
(43) Pub. Date: Oct. 6, 2011

(54) Glass sealing package and manufacturing method thereof

(75) Inventors: Chih-Che LIU, HSIN-CHU (TW); Shih-Feng HSU, HSIN-CHU (TW)

(73) Assignee: AU OPTRONICS CORPORATION, HSIN-CHU (TW)

(21) Appl. No.: 12/852,530

(22) Filed: Aug. 9, 2010

(30) Foreign Application Priority Data
Apr. 1, 2010 (TW) 99110196

(51) Int. Cl. H01L 33/48; H01L 21/50

(52) U.S. Cl. 257/99; 438/26; 257/E33.056; 257/E21.499

(57) ABSTRACT

Disclosed herein are a glass sealing package and a manufacturing method thereof. The glass sealing package includes a first glass substrate, a second glass substrate and a frit. The coefficient of thermal expansion of the frit lies between that of the two glass substrates. A light emitting element on the first glass substrate is situated in a sealed room formed among the two substrates and the frit. The method includes the steps of proving a first and a second glass substrate, dispensing a frit on the second glass substrate, pre-sintering the frit, assembling the two substrates, and sealing the frit to join the two substrates.

### RELATED APPLICATIONS

This application claims priority to Taiwan Application Serial Number 99110196, filed Apr. 1, 2010, which is herein incorporated by reference.

### BACKGROUND

1. Technical Field

The present invention relates to a sealing package. More particularly, the to present invention relates to a sealing package of a frit and a manufacturing method thereof.

2. Description of Related Art

In order to increase the air-tightness of the sealing between two glass substrates while manufacturing an organic light emitting diode (OLED) display panel, a frit is used as a medium to join the two glass substrates and to form an air-tight package of the display panel. During the manufacturing process, the frit is sintered to join with the two glass substrates so as to prevent the OLED from moisture intrusion and oxidation.

However, while sintering the frit, the entire display panel, including the upper glass substrate, the lower glass substrate and the frit material itself, is affected by the heat. The heat would cause the volume of the substrates and the frit to change in accordance with the temperature. Due to the fact that the coefficients of thermal expansion of these components are different from one another, the interface between adjacent components would therefore be subject to mechanical stress. Thus the coefficient of thermal expansion of each component becomes a crucial parameter in the manufacturing process. For example, in a case of the coefficients being unmatched with each other, the interfacial quality between adjacent components would be lowered, and the overall package quality is affected.

### SUMMARY

The invention provides a glass sealing package and a manufacturing method thereof to solve the problems caused by the interfacial mechanical stresses and to improve the sealing quality of the package.

According to one aspect of the invention, a glass sealing package is provided. The glass sealing package includes a first glass substrate, a second glass substrate and a fit. The first glass substrate has a first coefficient of thermal expansion and includes a light emitting element. The second glass substrate is disposed on one side of the first glass substrate in parallel and has a second coefficient of thermal expansion that is different from the first one. The frit has a third coefficient of thermal expansion lies between the first and the second coefficient of thermal expansion. The fit is disposed between the two glass substrates and forms a closed loop. A sealed room, where the light emitting element is situated, is formed among the two glass substrates and the frit.

In one embodiment, the first coefficient of thermal expansion, ranging from about 30 to about 100 10⁻⁷/° C., is higher than the second one. The third coefficient of thermal expansion ranges from about 30 to about 100 10⁻⁷/° C.

In another embodiment, the second coefficient of thermal expansion, ranging from about 30 to about 100 10⁻⁷/° C., is higher than the first one. the third coefficient of thermal expansion ranges from about 30 to about 100 10⁻⁷/° C.

According to another aspect of the invention, a method of manufacturing the glass sealing package is provided. The method includes the steps of providing a first glass substrate and a second substrate, dispensing a frit on the second glass substrate in a manner that the frit forms a closed loop, heating the second glass substrate to pre-sintering the frit, assembling the two glass substrates, and sealing the frit to join the two glass substrates. The two glass substrates have different coefficients of thermal expansion and the coefficient of thermal expansion of the frit lies between the two coefficients of the two glass substrates.

In one embodiment, the step of heating the second glass substrate includes the step of heating the second glass substrate and the frit at a temperature ranging from about 300 to about 500° C. In another embodiment, the step of sealing the frit includes the steps of sealing the frit by an IR laser at a pressure of about 1 atm and by heating the fit to a temperature ranging from about 600 to about 1100° C.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a glass sealing package according to one embodiment of the invention;

FIG. 2 is a flow chart of a method of manufacturing a glass sealing package according to one embodiment of the invention; and

FIGS. 3A-3G are perspective views corresponding to the steps in FIG. 2.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In the embodiments of the present invention, the coefficients of thermal expansion of the first glass substrate, the frit and the second glass substrate increase or decrease in a sequential order. Therefore the thermal stress applied to the glass sealing package is alleviated, which accordingly increases the package quality.

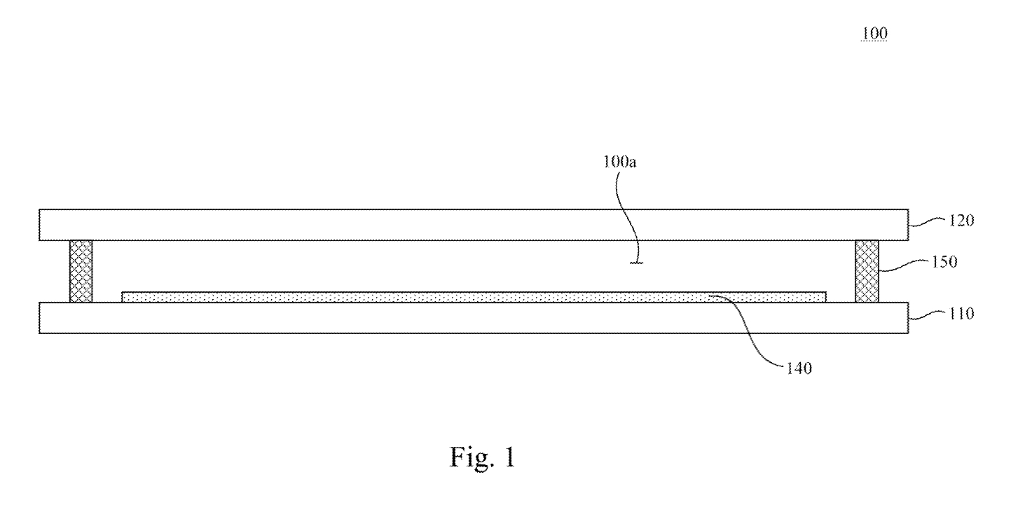

FIG. 1 is a cross-sectional view of a glass sealing package according to one embodiment of the invention. The glass sealing package 100 includes a first glass substrate 110, a second glass substrate 120 and a frit 150. The second glass substrate 120 is disposed on one side of the first glass substrate 110 in parallel. The frit 150 is disposed between the first glass substrate 110 and the second glass substrate 120 and forms a closed loop. The first glass substrate 110 has a first coefficient of thermal expansion, and the second glass substrate 120 has a second coefficient of thermal expansion that is different from the first one. The frit 150 has a third coefficient of thermal expansion that lies between the previous described first and second coefficient of thermal expansion. The first glass substrate 110 includes an organic light emitting element 140 that is disposed on a surface of the first glass substrate 110 facing the second glass substrate 120. A sealed room 100a is formed among the first glass substrate 110, second glass substrate 120 and the frit 150. The organic light emitting element 140 is situated in the sealed room 100a.

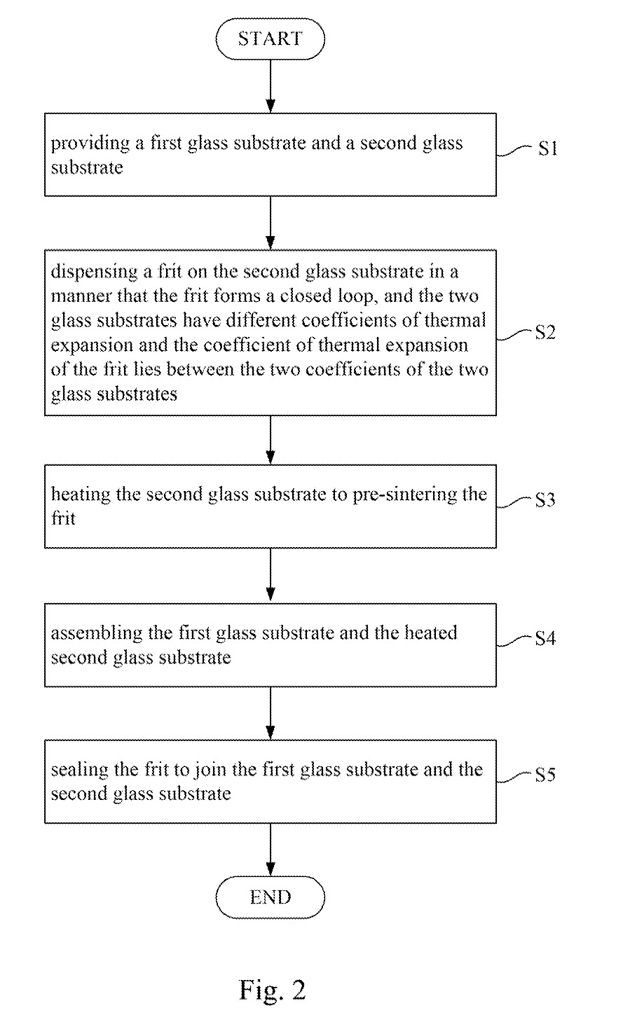

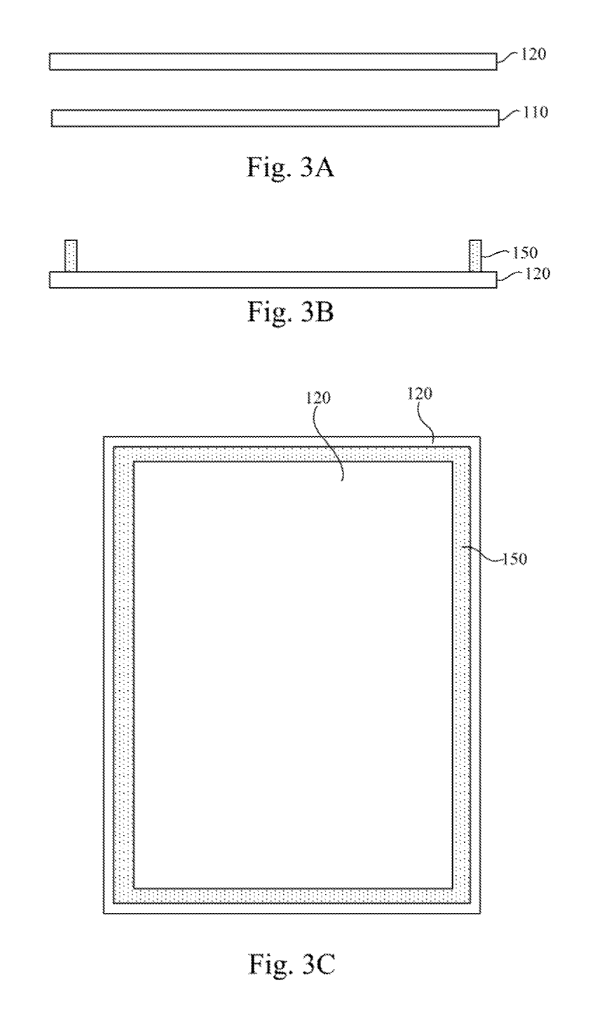

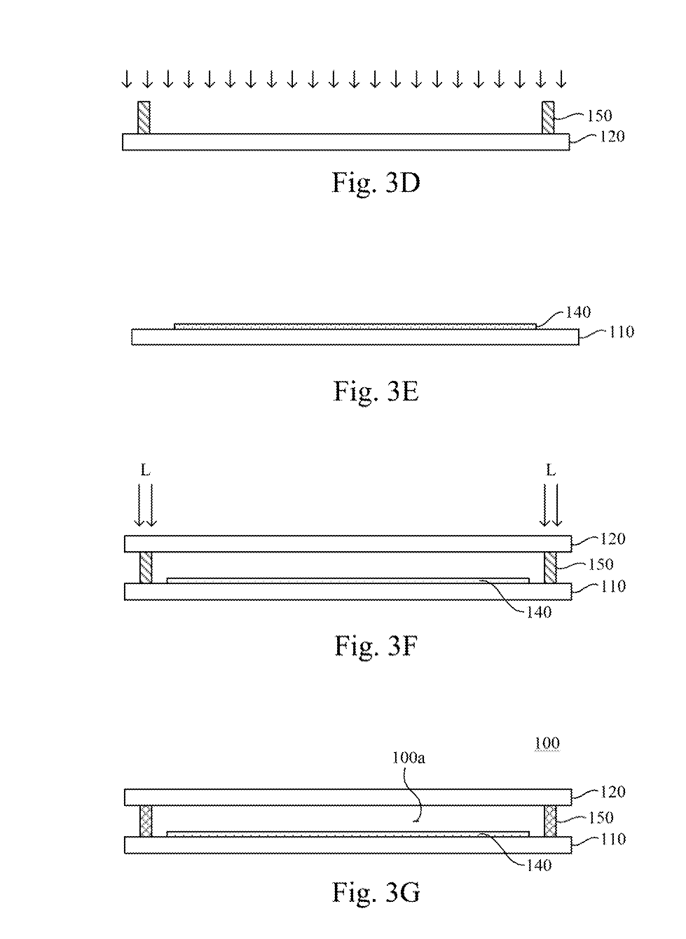

Next, the detail description directs to a method of manufacturing the glass sealing package 100 according to one embodiment of the invention with reference to FIG. 2 and FIGS. 3A-3G. FIG. 2 is a flow chart of a method of manufacturing a glass sealing package according to one embodiment of the invention. FIGS. 3A-3G are perspective views corresponding to the steps in FIG. 2.

In step S1, the method of the present embodiment first provides the first glass substrate 110 and the second glass substrate 120, as depicted in FIG. 3A.

In step S2, the frit 150 is dispensed on the second glass substrate 120. The frit 150 forms a closed loop on the second glass substrate 120, and is approximately to arranged adjacent to the edges of the second glass substrate 120, as shown in FIG. 3B and FIG. 3C. In the present embodiment, the first glass substrate 110 and the second glass substrate 120 respectively have the first coefficient of thermal expansion and the second coefficient of thermal expansion, in which the two coefficients are different. The frit 150 has the third coefficient of thermal expansion that lies between the first and the second coefficient of thermal expansion.

Practically, the first coefficient of thermal expansion may be either higher or lower than the second coefficient of thermal expansion. Exemplarily, the two coefficients individually range from about 30 to about 100 10−7/° C. The first glass substrate 110 and the second glass substrate 120 may be commercially obtainable transparent glass substrates. For example, the first glass substrate 110 or the second glass substrate 120 may be a Soda-Lime glass substrate that has a coefficient of thermal expansion of about 87 10⁻⁷/° C., a glass substrate of Corning® brand, model 7059 that has a coefficient of thermal expansion of about 46 10⁻⁷/° C., a glass substrate of Corning® brand, model 1737 that has a coefficient of thermal expansion of about 38 10⁻⁷/° C., a glass substrate of Corning® brand, model EAGLE2000 that has a coefficient of thermal expansion of about 32 10⁻⁷/° C., a glass substrate of Corning® brand, model EAGLE XG that has a coefficient of thermal expansion of about 32 10⁻⁷/° C., a glass substrate of NEG® brand, model OA-10 that has a coefficient of thermal expansion of about 38 10⁻⁷/° C., a glass substrate of NEG® brand, model OA-21 that has a coefficient of thermal expansion of about 33 10⁻⁷/° C., or a glass substrate of AGC® brand, model AN100 that has a coefficient of thermal expansion of about 38 10⁻⁷/° C.

On the other hand, in the present embodiment, the frit 150 includes transition metal oxide, metal oxide, silicon oxide or any combinations thereof, and, in addition, an organic solvent. The third coefficient of thermal expansion of the frit 150 ranges from about 30 to about 100 10−7/° C. The first glass substrate 110 and the second glass substrate 120 are not limited to the above-mentioned glass substrate models; any other commercially obtainable glass substrates are applicable in the present invention, depending on the product needs. In addition to that, any suitable first glass substrate and second glass substrate with different coefficients of thermal expansion and any suitable frit with a coefficient of thermal expansion that lies between the two coefficients of the two glass substrates are eligible to be used in the method of the present invention.

In step S3, the method of the present embodiment moves on to the step of heating the second glass substrate 120 to pre-sintering the frit 150, as depicted in FIG. 3D. In one embodiment, the second glass substrate 120 and the frit 150 dispensed thereon are heated at a temperature ranging from about 300 to about 500° C.; in a further embodiment, at a temperature ranging from about 350 to about 460° C. In step S3, the fit 150 is cured and solidified as the organic solvent being volatized by the heat.

Further, the method of the present embodiment performs the step of forming the organic light emitting element 140 on the first glass substrate 110, as depicted in FIG. 3E. The organic light emitting element 140 is exemplified by several stacked material layers on the first glass substrate 110. In the present embodiment, the organic light emitting element 140 is formed on the first glass substrate 110 through an evaporation process at a pressure ranging from about 10⁻³ to about 10⁻⁵ torr, preferably at a pressure of 10⁻⁴ torr. The step of forming the organic light emitting element 140 is not limited to be performed afterward step S3; it may also be performed between step S1 and step S2, or between step S2 and step S3.

In step S4, the method of the present embodiment moves on to the step of assembling the first glass substrate 110 and the second glass substrate 120. Preferably, the first glass substrate 110 and the heated second glass substrate 120 are assembled at a pressure of about 10⁻² torr. After the first glass substrate 110 and the second glass substrate 120 are assembled, the frit 150 and the organic light emitting element 140 are situated between the two glass substrates 110 and 120.

In step S5, the step of sealing is performed. The first glass substrate 110 and the second glass substrate 120 are joined with each other through the frit 150. In one embodiment, the frit 150 is heated and sintered by an IR laser L at a pressure of about 1 atm, as depicted in FIG. 3F. Due to the fact that the third coefficient of thermal expansion of the frit 150 lies between the first and the second coefficient of thermal expansion of the two glass substrates 110 and 120, the effect of the thermal stress among the first glass substrate 110, the second glass substrate 120 and the frit 150 can be alleviated. The interface reliability can therefore be increased.

More specifically, in step S5, the frit 150 is irradiated by the IR laser L from a side of the second glass substrate 120 that is opposite to the first glass substrate 110, and the frit 150 is heated to a temperature ranging from about 600 to about 1100° C. so as to be sintered. The wavelength of the IR laser L approximately ranges from about 810 to about 940 nm.

After the frit 150 is sintered and sealed between the two glass substrates 110 and 120, the glass sealing package 100 of the present embodiment is completed, as depicted in FIG. 3G. The glass sealing package 100 of the present embodiment can be exemplified by an OLED display panel, which generates light from the organic light emitting element 140 on the first glass substrate 110. The sealed room 100a is formed among the sealed first glass substrate 110, frit 150 and the second glass substrate 120. In another embodiment, the glass sealing package 100 may be sealed in a moisture-free and oxide-free environment, so as to ensure that the sealed room 100a is in a moisture-free and oxide-free state. Therefore, the erosion and the oxidation to the organic light emitting element 140 can be prevented, and the damage of materials and the reduction of luminescence efficiency can be avoided.

In the above-mentioned glass sealing package and the manufacturing method thereof, the first glass substrate and the second glass substrate have different coefficients of thermal expansion, and the coefficient of the frit lies between the two coefficients of the two glass substrates. As a result, while sealing the package, the effect of the thermal stress at the interfaces is alleviated, and the sealing quality of the glass sealing package is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A glass sealing package, comprising:
a first glass substrate having a first coefficient of thermal expansion and including a light emitting element;
a second glass substrate disposed on one side of the first glass substrate in parallel and having a second coefficient of thermal expansion that is different from the first coefficient of thermal expansion; and
a frit having a third coefficient of thermal expansion lies between the first and the second coefficient of thermal expansion, wherein the frit is disposed between the first and the second glass substrate and forms a closed loop, and a sealed room, where the light emitting element is situated, is formed among the two glass substrates and the frit.

2. The glass sealing package of claim 1, wherein the first coefficient of thermal expansion is higher than the second coefficient of thermal expansion, and the first coefficient of thermal expansion ranges from about 30 to about 100 10⁻⁷/° C.

3. The glass sealing package of claim 1, wherein the second coefficient of thermal expansion is higher than the first coefficient of thermal expansion, and the second coefficient of thermal expansion ranges from about 30 to about 100 10⁻⁷/° C.

4. The glass sealing package of claim 2, wherein the third coefficient of thermal expansion ranges from about 30 to about 100 10⁻⁷/° C.

5. The glass sealing package of claim 3, wherein the third coefficient of thermal expansion ranges from about 30 to about 100 10⁻⁷/° C.

6. The glass sealing package of claim 1, wherein the frit includes transition-metal oxide, metal oxide, silicon oxide, or any combinations thereof.

7. A method of manufacturing a glass sealing package, comprising:
(a) providing a first glass substrate and a second glass substrate;
(b) dispensing a frit on the second glass substrate in a manner that the frit forms a closed loop, wherein the two glass substrates have different coefficients of thermal expansion and the coefficient of thermal expansion of the frit lies between the two coefficients of the two glass substrates;
(c) heating the second glass substrate to pre-sintering the frit;
(d) assembling the first glass substrate and the heated second glass substrate; and
(e) sealing the frit to join the first glass substrate and the second glass substrate.

8. The method of claim 7 further comprising:
forming a light emitting element on the first glass substrate.

9. The method of claim 7, wherein the step (c) comprises:
heating the second glass substrate and the frit on the second glass substrate at a temperature ranging from about 300 to about 500° C.

10. The method of claim 7, wherein the step (e) comprises:
sealing the frit by an IR laser at a pressure of about 1 atm.

11. The method of claim 10, wherein the step (e) further comprises:
sealing the frit by heating the frit to a temperature ranging from about 600 to about 1100° C.
